(19) United States
(12) Patent Application Publication
(10) Pub. No.: US 2018/0158639 A1
(43) Pub. Date: Jun. 7, 2018

(54) TARGET FOR BARIUM-SCANDATE DISPENSER CATHODE

(71) Applicant: KONINKLIJKE PHILIPS N.V., EINDHOVEN (NL)

(72) Inventors: GEORG FRIEDRICH GAERTNER, AACHEN (DE); WILHELMUS CORNELIS KEUR, WEERT (NL)

(21) Appl. No.: 15/869,352

(22) Filed: Jan. 12, 2018

Related U.S. Application Data
(63) Continuation of application No. 14/236,145, filed on Jan. 30, 2014.
(60) Provisional application No. 61/514,521, filed on Aug. 3, 2011.

(51) Int. Cl. H01J 1/142; C23C 14/08; H01J 23/04; C23C 14/34; H01J 1/28

(52) U.S. Cl. CPC H01J 1/142; C23C 14/082; H01J 23/04; H01J 1/28; C23C 14/3414

(57) ABSTRACT

The invention relates to the field of production of barium-scandate dispenser cathodes or other barium-scandate materials. A target (66) containing a mixture of BaO, CaO, Al₂O₃ and Sc₂O₃ tends to be more stable, the higher the scandia (scandium oxide) content is. However, an increased scandia content results in a reduced emission capability. A destabilizing effect of BaO and CaO reactions is counteracted by the more inert Sc₂O₃ and also Al₂O₃ components, as not only an increased scandia content stabilizes the material but also an increased alumina (aluminum oxide) content improves the stability.

The invention relates to the field of production of barium-scandate dispenser cathodes or other barium-scandate materials. In particular the present invention relates to a target material for physical thin film deposition used in a production of barium-scandate dispenser cathodes, a target made of such target material, the use of such target material in a production of a barium-scandate dispenser cathode, a method of producing a barium scandate dispenser cathode and a method for producing such target for physical thin film deposition for use in a production of barium-scandate dispenser cathodes.

Highly emissive top-layer barium-scandate dispenser cathodes—capable of high electron emission—are produced by means of Laser Ablation Deposition (LAD) or other physical deposition methods such as sputtering using suitable targets, wherein it is generally aimed for stable targets allowing reproducible and reliable preparation.

Such dispenser cathodes are used or could be used in a variety of vacuum tubes, especially for electron beam lithography, but also in cathode ray tubes for television, in high frequency tubes, in microwave tubes, in X-ray tubes, in thermionic converters et cetera. Top-layer barium-scandate cathodes typically contain barium Ba and scandium Sc together with oxygen O in form of a surface complex and in the form of dispensing compounds on or/and in (as impregnants) a matrix base (for example, tungsten W), wherein the top-coating further contains a suitable metal, e.g. rhenium Re. With such dispenser cathode, atomic Ba is generated during an interface reaction of the impregnant with the matrix base, wherein the generated Ba reaches the Sc₂O₃ particles in the outer layer by the relatively slow surface diffusion and diffusion through the solid base.

Methods for producing such cathodes and compositions and structures of such cathodes, which are able to supply 300-400 A/cm² saturated electron emission current density at about 1030° C. true temperature, have previously been described in the EP 0 757 370 A1, DE 198 28 729 A1 and DE 199 61 672 A1, for example.

A problem involved with some conventional target materials for LAD or other comparable thin film deposition methods (providing ultra-fine particles or compact layers) is that the respective targets showed insufficient mechanical stability for reproducible manufacturing of a large number of the above cathodes.

One example of a conventional dispenser cathode includes a first intermediate LAD layer on a W base, which consists of 4BaO.CaO.Al₂O₃.y Sc₂O₃ (0.2<y<1) (see, for example, DE 198 28 729 A1). The known targets proved to be problematic compared to the Re and Sc₂O₃ targets used for other layers. The provision of such intermediate layer is, however, highly desirable in order to obtain a sufficient amount of the highly emissive {Ba, Sc, O} surface complex during initial cathode activation at elevated temperatures.

For conventional dispenser cathodes an activation process is provided, during which, typically, under ultra high vacuum and at temperatures above the usual operation temperature of the cathode the highly emissive {Ba, Sc, O} surface complex (more specifically a surface layer containing a (Ba, Sc, O) containing complex of a thickness in the order 10 to 500 nm) is generated from Sc₂O₃ and atomic Ba and/or from a reaction of Sc₂O₃ and BaO provided in the intermediate layer. For example, in the case of thermionic rhenium-barium-scandate cathodes, a relatively long additional activation period is observed of approximately 100 h after an initial activation process of 2 h, until finally a saturated emission i_{10%} of about 300 to 400 A/cm² is reached.

The usual operation temperature referred to above is in this case approx. 965° C._{Mo-Br} (Mo—Br=molybdenum brightness=radiation temperature), which is pyrometrically measured on the Mo-cap of the cathode unit, wherein 965° C._{Mo-Br} corresponds to a true temperature of about 1033° C.

It is desirable to reduce or even completely avoid the additional activation period after the initial activation process, i.e. to obtain the optimum emission as soon as possible while maintaining it throughout the service life (>5000 h) of the cathode.

In the context of barium-scandate dispenser cathodes, it is an object of the invention to provide for an intermediate layer allowing for such reduction or omission of the additional activation period, while the target for generating such intermediate layer by means of physical thin film deposition is sufficiently stable, in particular in mechanical terms, and allows for a reliable and reproducible production. In a more general context, it is an object to provide a target for generating a barium-scandate layer by means of physical thin film deposition, which target is sufficiently stable, in particular in mechanical terms, and allows for a reliable and reproducible production.

This object is achieved by a target material for physical thin film deposition used in a production of barium-scandate dispenser cathodes or other barium-scandate materials, wherein the target material comprises or consists of a mixture of barium oxide BaO, calcium oxide CaO, aluminium oxide Al₂O₃ and scandium oxide Sc₂O₃, wherein the molar ratio of BaO:CaO:Al₂O₃:Sc₂O₃ is b:c:x:y with 2≤b≤5, 1≤c≤3, 2≤x+y≤b+c and 0.1≤y≤1.

The present invention further provides for a use of a target material in a production of a barium-scandate dispenser cathode or other barium-scandate materials, wherein the target material comprises or consists of a mixture of barium oxide BaO, calcium oxide CaO, aluminium oxide Al₂O₃ and scandium oxide Sc₂O₃, wherein the molar ratio of BaO:CaO:Al₂O₃:Sc₂O₃ is b:c:x:y with 2≤b≤5, 1≤c≤3, 2≤x+y≤b+c and 0.1≤y≤1.

The object is also achieved by a method of producing a barium scandate dispenser cathode, comprising the steps of: providing a porous metal body having a surface and being impregnated with one or more compounds for dispensing at least barium and scandium to the surface, providing an intermediate layer consisting of or comprising BaO, CaO, Al₂O₃, and Sc₂O₃ by means of physical thin film deposition on the porous metal body, and providing an outer metal layer, wherein for the physical thin film deposition of the intermediate layer a target material is used comprising or consisting of a mixture of barium oxide BaO, calcium oxide CaO, aluminium oxide Al₂O₃ and scandium oxide Sc₂O₃, wherein the molar ratio of BaO:CaO:Al₂O₃:Sc₂O₃ is b:c:x:y with 2≤b≤5, 1≤c≤3, 2≤x+y≤b+c and 0.1≤y≤1.

The present invention also provides for a method for producing a target for physical thin film deposition for use in a production of barium-scandate dispenser cathodes or other barium-scandate materials, providing a mixture of barium oxide BaO, calcium oxide CaO, aluminium oxide Al₂O₃ and scandium oxide Sc₂O₃, sintering or melting the mixture to form the target, wherein the molar ratio of BaO:CaO:Al₂O₃:Sc₂O₃ in the target is b:c:x:y with 2≤b≤5, 1≤c≤3, 2≤x+y≤b+c and 0.1≤y≤1.

According to a particular embodiment, the target material further comprises one or more oxide selected from the group consisting of strontium oxide SrO, lanthanum oxide La₂O₃, yttrium oxide Y₂O₃ and europium oxide Eu₂O₃ (i.e. SrO, La₂O₃, Y₂O₃ and/or Eu₂O₃) in addition to the barium oxide and/or one or more oxides of one or more rare earth elements or a mixture of oxides of rare earth elements with scandium as main rare earth element in addition to the scandium oxide.

In particular, the addition of europia (europium oxide) and/or yttria (yttrium oxide) was found to be helpful for, for example, emission lifetime of the resulting cathodes. A preferred range for the added amount of europia, if any, is 10 ppm to 1% in weight of the target material in total. A preferred range for the added amount of yttria, if any, is 10 to 250 ppm.

In case of use of La₂O₃, in addition to BaO for example, a layer resulting from the thin film deposition according to the present invention has a defect structure in comparison to the use of just BaO, for example, Ba_{1.80}La_{0.13}ScAlO₅ instead of Ba₂ScAlO₅. A preferred range for the added amount L of lanthanum oxide is 0≤L≤y or 0≤L≤0.15. Further, a preferred range for the added amount S of strontium oxide is 0≤S≤1.

The inventors assume that providing a defect structure as indicated above leads to an improvement as to the release characteristic for barium.

A preferred range for the added amount R of the one or more oxides of one or more rare earth elements or an mixture of oxides of rare earth elements with scandium as main rare earth element in addition to the scandium oxide is ≤33%.

In a mixture of oxides of rare earth elements with scandium as main rare earth element, the molar amount of scandium is at least 3 times larger than the combined molar amounts of the other rare earth elements.

As to the provision of oxides of Sr, La, Y and/or Eu in addition to the barium oxide and of other rare earth elements in addition to the scandium oxide, respectively, depending of the atomic size of the rare earth element and of the earth alkaline element all kinds of additions or defects are possible within certain limits which are understood by the person skilled in the art.

It is to be noted that the values of the placeholders b, c, x and y discussed here are not limited to integer values, even though often examples having integer values for b, c and x like b=4, c=1, x=1; b=3, c=1, x=1; orb=5, c=3, x=1 are conventionally used. It is to be understand that also fractions are possible for these values, resulting in the desired effects for the dispenser cathodes, provided a contact with the material of the wall of the pores (for example, tungsten) is ensured for the cathode.

For the conventionally produced top-layer barium-scandate cathodes, either the intermediate layer did not have the desired properties and necessitated the above mentioned additional activation period, as the available LAD targets or target materials did not provide the desired composition of the intermediate layer, or the production was not reliable and reproducible enough, as the targets or target materials did not exhibit sufficient (mechanical) stability. The present invention, however, is aimed at overcoming these shortcomings.

It was found by the inventors that a target containing a mixture of BaO, CaO, Al₂O₃ and Sc₂O₃ tends to be more stable, the higher the scandia (scandium oxide) content is. However, an increased scandia content results in a reduced emission capability, as apparently a sufficiently high Ba/Sc ratio is needed. Preferably, the Ba/Sc ratio was found to be greater than 1, presumably due to the complex composition and also due to the strong loss of the volatile Ba/BaO during activation.

It was further found by the inventors that the reason for the instability is caused by BaO and CaO reacting with CO₂ and water in air accompanied by grain expansion and powderization.

According to the present invention, the destabilizing effect of BaO and CaO reactions is counteracted by the more inert Sc₂O₃ and also Al₂O₃ components, as it was further found by the inventors that not only an increased scandia content stabilizes the material but also an increased alumina (aluminum oxide) content improves the stability.

Thus, according to the present invention, the target material, which might be prepared typically in cylindrical form either by pressing or sintering or from the melt, provides still a somewhat low scandium content (maintaining the desired Ba/Sc ratio), while the alumina content is increased in comparison to the known target materials, thus obtaining targets being stable versus exposure to air and exhibiting a high Ba/Sc ratio at the same time. The fulfulling of the conditions 2≤b≤5, 1≤c≤3, 2≤x+y≤b+c and 0.1≤y≤1 for ab:c:x:y target material (in the following abbreviated as bcxy) exhibits desirable characteristics. For example, a material with b=4, c=1 (in the following abbreviated as 41xy) ensures Ba/Sc>4 suitable for high emission, and also (Ba+Ca):(Al+Sc)>5:4 providing for very stable targets.

It appears decisive for avoiding or reducing the additional activation period that there is a sufficient supply of Ba (compensating for and replenishing against the losses of Ba during initial activation).

According to the present invention, there is provided for an intermediate layer on the matrix base having a suitable composition for providing such supply.

Tests conducted by the inventors showed the following:

Initially, targets were produced from molten 411 impregnant (4BaO.CaO.Al₂O₃) combined with y Sc₂O₃ (y preferably in the range from 0.2 to 0.6, in particular y=0.25), in order to provide an increased amount of emissive barium-scandate ({Ba—Sc—O}-complex) without completely depending on Ba produced by the reaction between the impregnant and the matrix base (tungsten).

Further, top-layer scandate cathodes were studied using known stable barium-scandates like BaSc₂O₄, Ba₂Sc₂O₅, Ba₃Sc₄O₉ for the intermediate layer. These compounds all have an atomic ratio Ba:Sc smaller than or equal to 1. It was found that these materials do not lead to improvements as to emission or service life. Actually, in contrast, substantial worsening as to the emission characteristics was found.

By means of high resolution surface examination on highly emissive scandate cathodes it was further found that at the surface there is provided a complex having a Ba:Sc ratio of larger than 1. As Ba/BaO tends to evaporate much faster in comparison to Sc₂O₃, it was realized by the inventors that a target material is needed also having a Ba:Sc ratio (preferably much) larger than 1.

By means of a 411-0.25 target obtained from molten 411 material (i.e. Ba:Sc=8) good results are obtainable in terms of emission. However, it was found that such targets are mechanically unstable—despite dry storing—and are crumbling within short. 411-0.35 targets (i.e. Ba:Sc≈6) provide for still sufficient emission properties and exhibit slightly better mechanical stability. 411y targets with y>0.5 proved to be mechanically stable. However, the emission characteristics of the obtained cathode were substantially reduced.

The above findings were confirmed by comparing the properties of cylindrical targets (particularly suitable for LAD) obtained via melting (possible up to y=0.5) and obtained by pressing and sintering, which also showed that targets with y=0.5 are less stable than those with y=1 (Ba:Sc=2).

Thus, increasing the scandia content in the target increases the mechanical stability of the target but detriments the emission performance and vice versa.

The present inventors took to identify the cause for the lack of mechanical stability and to eventually find target materials having sufficient stability allowing for long term use in a production environment.

It was found that a substantial cause of a lack of mechanical stability is a reaction between BaO and CaO and CO₂ and water of the surrounding atmosphere, resulting in the generation of BaCO₃, CaCO₃ and barium- and calcium-hydroxides. These compounds have a differing density and thermal expansion coefficient. The resulting stress causes the target to crumble, i.e. to break down into powder/grains. Even though this consequence is most severe in the case of pressed and sintered targets (having porosity), this crumble also occurs in targets obtained by melting, presumably due to too large crystallites.

Al₂O₃ and Sc₂O₃ do not react in the above way with CO₂ or water and have therefore a stabilizing effect on the target as a whole, which becomes significant in particular in the range of increasing amount beyond (Ba,Ca):Sc=5:2.

By means of the present invention, the stabilizing effect of Al₂O₃ and Sc₂O₃ is utilized to allow for a desirable ratio of Ba/Sc (for example >4) (providing for high emission), wherein a ratio of (Ba+Ca):(Al+Sc) (for example >5:4) allows for very stable targets.

The stability of targets according to the present invention (in particular also in view of exposure times of more than 1 year) provides a substantial contribution to achieving constant deposition conditions and thus reproducible production of dispenser cathodes in large numbers.

According to a particular embodiment, the target material satisfies 0.1<y<0.5. It was found that a higher Ba:Sc ratio is favorable for high emission. According to a further advantageous embodiment favorable for high emission, the target material satisfies 0.1<y<0.4. According to particularly preferred embodiments, the target material satisfies y=0.35 or y=0.25.

According to a further particular embodiment, the target material satisfies b:c being one of 4:1, 3:1, or 5:3. Such ratios as used for an impregnant of an impregnated cathode are found to be ensuring good barium replenishment from the cathode pores to the surface. This then also helps for barium supply from the BaO containing target material with a tungsten base, for example.

According to a particular embodiment, the target material further comprises one or more oxides of two or more elements selected from the group consisting of barium, calcium, aluminium and scandium. Such oxides may be added for improving the stability of the resulting target.

In addition to including further oxides in the target material prior to producing the target as such, the target production (e.g. sintering or melting) may also result in further compounds due to internal reactions, wherein an example according to a further embodiment of the invention is Ba₂ScAlO₅ included in the target, which exhibits improved stability.

These and other aspects of the invention will be apparent from and elucidated with reference to the embodiments described hereinafter.

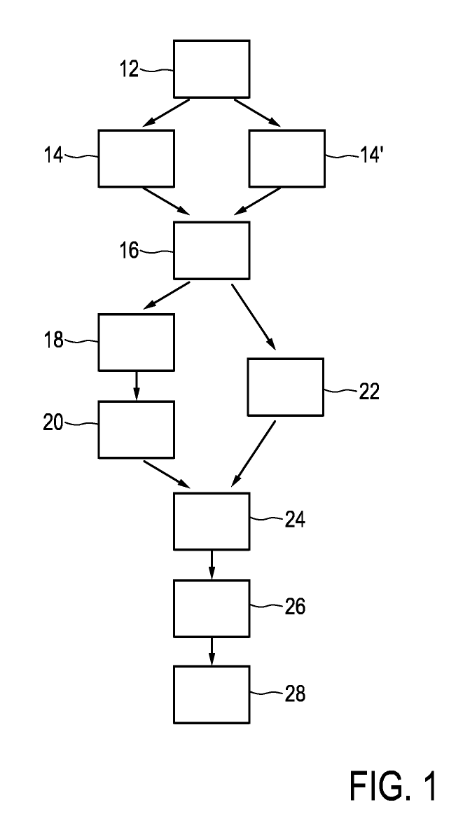

FIG. 1 shows alternative embodiments of a method for producing a target according to the present invention,

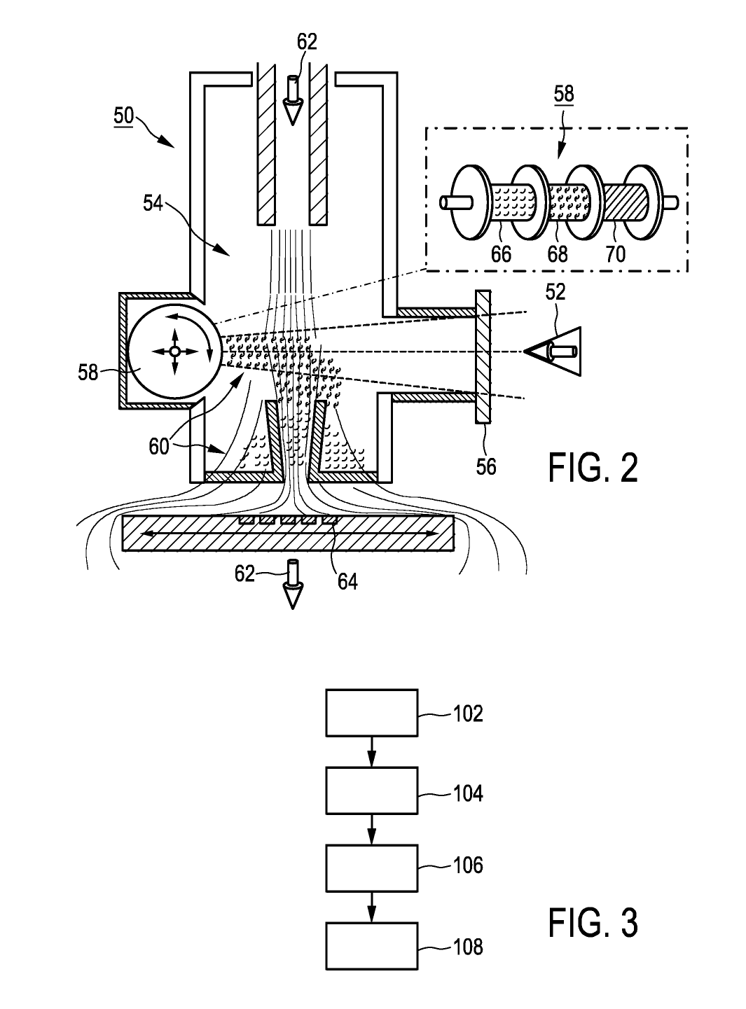

FIG. 2 shows an illustration of a LAD arrangement using a target according to the present invention, and

FIG. 3 shows an embodiment of a method producing a barium scandate dispenser cathode according to the present invention.

FIG. 1 shows alternative embodiments of a method for producing a target according to the present invention. Starting with a solution with appropriate amounts of constituents dissolved to obtain 411 material (BaO, CaO, Al₂O₃ in the molar ratio of 4:1:1), the precipitate is formed (step 12) and the oxides are generated in a suitable furnace at 1400° C. under an atmosphere of O₂ or H₂ (steps 14 or 14′). Sc₂O₃ and Al₂O₃ are added and mixed to the resulting powder (step 16). Alternatively, the Al₂O₃ and Sc₂O₃ may also be added to the suspension.

Alternatively to or supplementing the above, it is also possible to do the decomposition of the precipitate (hydroxide/carbonates) at 1400° C. in vacuum or under an inert atmosphere, for example argon, helium, or N₂.

In the case of sintering, the mixed powder (i.e. the target material) is then pressed with high pressure into a cylindrical form (step 18) and sintered (step 20) at a temperature in the range from 1650° C. to 1700° C.

Alternatively, the target material is molten (step 22), which, however, necessitates a higher temperature beyond 1700° C.

The sintering or melting of the 411y in Mo-crucibles around 1650° C. up to or beyond 1700° C. should be carried out under an atmosphere containing no (or at least substantially no) H₂O or O₂. In order to avoid gas inclusions (holes inside the target formed) H₂ is preferred (also due to the reducing functionality to keep the crucible intact). Helium is a good option, as atoms/molecules like H₂ and He are small enough to escape.

Even though argon, N₂ or mixed gasses like N₂/H₂ or Ar/H₂ are possible to be used, the above mentioned options are preferred, as these latter gasses and mixtures are difficult to remove out of a sintered target or may result in (oxy)nitride compounds being formed. In view of the volatility of BaO, H₂ and He are also preferred over vacuum.

Depending on the composition of the target material, mixed phases of the components may be obtained, for example, Ba₂ScAlO₅, which further improve the resistance against and the stability under air including moisture.

Unless the target is already provided with a bore during the above steps, the resulting target is provided (step 24) with such bore for mounting the target on a common axis with other target for use in the production of the dispenser cathode by means of LAD.

Depending on the circumstances, further mechanical handling of the targets may be necessary (for example, shortening/cutting the cylinder) (step 26).

In order not to compromise the mechanical stability, the mechanical handling should not include the use of water or moisture. Preferably, the handling should be provided either in a dry manner or using liquids other than water and not reacting with the components of the target. Suitable liquids are isopropanol or decan. Upon drilling, furthermore, a cooling may be provided by a stream of an inert gas.

After the handling, a step 28 of further baking (under O₂ or dry air) at approx. 1400° C. is provided in this embodiment for reverting any chemical changes at the surface.

In case of other deposition methods, e.g. sputtering, a bore is not necessary, wherein the intended deposition method influences generally the geometry of the target.

In one example, 411-carbonate powder was mixed with 0.65 Al₂O₃ and 0.35 Sc₂O₃ (mol ratio) and then transformed to oxides at 1400° C. The resulting powder was pressed into a cylindrical form (including a central pin) and sintered under H₂ at 1600° C. After cooling, the target cylinder was cut to length and heated again to 1000° C. to 1400° C. under 02 or dry air. The target thus obtained was stable and did not exhibit any weight gain under air.

FIG. 2 shows an illustration of a LAD arrangement 50 using a target according to the present invention.

In principle, the skilled person is familiar with the process of Laser Ablation Deposition (LAD) and therefore a detailed explanation of the process and the arrangement may be omitted.

The LAD arrangement 50 of FIG. 2 includes a KrF excimer laser 52 (λ□=248 nm) of about 60 W average power and maximum pulse energy of 6 Joule, which is well suited for LAD of refractory metals such as W or Re due to electronic instead of thermal excitation. The beam of the excimer laser 52 is guided into a stainless steel ablation chamber 54 (with UHV) through a UV quartz window 56, so that it hits a rotating cylindrical multi-target 58. A plasma plume 60 with ablated ultrafine particles forms above the target and the ultra fine particles are carried by the carrier gas (illustrated by arrow 62) to the substrates 64. A further view of the cylindrical multi-target 58 including target material 66 according to the present invention (41xy), Sc₂O₃-material 68 and Rhenium-material 70 is inserted into FIG. 2.

FIG. 3 shows an embodiment of a method producing a barium scandate dispenser cathode according to the present invention

In step 102, a porous metal body being impregnated with one or more compounds for dispensing at least barium and scandium to the surface is provided. In step 104, an intermediate layer consisting of or comprising BaO, CaO, Al₂O₃, and Sc₂O₃ is provided by means of LAD as an example of physical thin film deposition on the porous metal body. Furthermore, in step 106, an outer metal layer is provided. Finally, in step 108, the dispenser cathode is completed. The details of these steps correspond to those of conventional steps for producing a dispenser cathode, except for the used target (material) according to the present invention.

Preferably, the surface of the target should be smooth and—in the case of LAD—should be ablated in a constant distance to the laser optics and under constant conditions. This includes a uniform ablation of the target surface by means of a suitably directed scan and the removal of surface areas or portions showing chemical changes.

For the purpose of LAD, a flat geometry of the target (target in a rectangular cup) is not very suitable, as the target has to be combined with other—typically cylindrical—targets, e.g. for Re and Sc₂O₃, wherein furthermore cylindrical targets at rotation offer a significantly larger surface to the ablation with the same amount of material. A reduced ablation depth is preferable in term of a reduced roughness of the surface and an increased usability of the target.

Above, the explanation is primarily focused on a 41xy target material, even though the present invention is not limited thereto. Other compositions are also encompassed by the present invention. e.g. as indicated by 53xy or 31xy. In general, a suitable material may be indicated by bcxy (b: BaO, c: CaO, x: Al₂O₃ and y: Sc₂O₃), with b:c:x:y with 2≤b≤5, 1≤c≤3, 2≤x+y≤b+c and 0.1≤y≤1, preferably 0.1<y<0.5, particularly preferred 0.1<y<0.4.

The described target materials are not limited to LAD applications for top-layer barium scandate dispenser cathodes but may also be used as target materials (or having analogue composition) for production of, for example, phosphors, high temperature superconductors or ceramic layers, including Ba and/or Ca and/or Sr, mixed with an inert oxide, e.g. one or more oxides of the Sc-group or of rare earths or magnesium oxide.

The present description focusses on physical thin film deposition. Other methods of deposition, e.g. using dissolved metal salts (spinning/dipping/spraying/chemical batch deposition) or organometal compounds (e.g. CVD) including a heating step under an oxygen atmosphere and/or an atmosphere containing H₂O for decomposing compounds into oxides, seem currently not suitable for producing barium-scandate dispenser cathodes, as the porous metal body (made of tungsten or molybdenum) will undergo oxidation. If, however, a further method becomes available which is similar in its use to current methods of physical thin film deposition, the present invention is to be understood as being applicable also thereto.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. A deposition apparatus comprising a target material, the target material comprising:
a mixture of barium oxide BaO, calcium oxide CaO, aluminum oxide Al₂O₃ and scandium oxide Sc₂O₃,
wherein the molar ratio of BaO:CaO:Al₂O₃:Sc₂O₃ is b:c:x:y with 2≤b≤5, 1≤c≤3, 2≤x+y≤b+c and 0.1≤y≤1; and
Ba₂ScAlO₅, wherein the target material is configured for physical thin film deposition in a production of barium-scandate dispenser cathodes or other barium-scandate materials.

2. The deposition apparatus according to claim 1, wherein the target material further comprises one or more oxide selected from the group consisting of strontium oxide SrO, lanthanum oxide La₂O₃, yttrium oxide Y₂O₃ and europium oxide Eu₂O₃ in addition to the barium oxide, and/or one or more oxides of one or more rare earth elements or a mixture of oxides of rare earth elements with scandium as main rare earth element in addition to the scandium oxide.

3. The deposition apparatus according to claim 1, wherein 0.1<y<0.5.

4. The deposition apparatus according to claim 1, wherein b:c is one of 4:1, 3:1, or 5:3.

5. The deposition apparatus according to claim 1, further comprising one or more oxides of two or more elements selected from the group consisting of barium, calcium, aluminum and scandium.

6. A deposition apparatus comprising a target, the target comprising:
a mixture of barium oxide BaO, calcium oxide CaO, aluminum oxide Al₂O₃ and scandium oxide Sc₂O₃, wherein the molar ratio of BaO:CaO:Al₂O₃:Sc₂O₃ is b:c:x:y with 2≤b≤5, 1≤c≤3, 2≤x+y≤b+c and 0.1≤y≤1; and Ba₂ScAlO₅, wherein the target is configured for physical thin film deposition.

7. A use of a target material of a deposition apparatus:
wherein the target material comprises or consists of a mixture of barium oxide BaO, calcium oxide CaO, aluminum oxide Al₂O₃ and scandium oxide Sc₂O₃,
wherein the molar ratio of BaO:CaO:Al₂O₃:Sc₂O₃ is b:c:x:y with 2≤b≤5, 1≤c≤3, 2≤x+y≤b+c and 0.1≤y≤1; and
wherein the use of the target material is in a production of a barium-scandate dispenser cathode or other barium-scandate materials.

8. The use of the target material according to claim 7, wherein the target material is used in a physical thin film deposition step for generating an intermediate layer consisting of or comprising BaO, CaO, Al₂O₃, and Sc₂O₃ in the dispenser cathode.

9. A method of producing a barium scandate dispenser cathode, comprising:
providing a porous metal body having a surface and being impregnated with one or more compounds for dispensing at least barium and scandium to the surface,
providing an intermediate layer consisting of or comprising BaO, CaO, Al₂O₃, and Sc₂O₃ by means of physical thin film deposition on the porous metal body, and
providing an outer metal layer, wherein for the physical thin film deposition of the intermediate layer a target material is used comprising or consisting of a mixture of barium oxide BaO, calcium oxide CaO, aluminum oxide Al₂O₃ and scandium oxide Sc₂O₃; and
wherein the molar ratio of BaO:CaO:Al₂O₃:Sc₂O₃ is b:c:x:y with 2≤b≤5, 1≤c≤3, 2≤x+y≤b+c and 0.1≤y≤1.

10. The method according to claim 9, wherein the physical thin film deposition includes laser ablation deposition and/or sputtering.

11. A device including a barium scandate dispenser cathode produced by a method according to claim 10.

12. A method for producing a target of a deposition apparatus, the method comprising:
providing a mixture of barium oxide BaO, calcium oxide CaO, aluminum oxide Al₂O₃ and scandium oxide Sc₂O₃,
sintering or melting the mixture to form the target, wherein the molar ratio of BaO:CaO:Al₂O₃:Sc₂O₃ in the target is b:c:x:y with 2≤b≤5, 1≤c≤3, 2≤x+y≤b+c and 0.1≤y≤1; and wherein the method is for producing the target for physical thin film deposition for production of barium-scandate dispenser cathodes or other barium-scandate materials.

13. A deposition apparatus comprising a target material, the target material comprising:
a mixture of barium oxide BaO, calcium oxide CaO, aluminum oxide Al₂O₃ and scandium oxide Sc₂O₃, wherein the molar ratio of BaO:CaO:Al₂O₃:Sc₂O₃ is b:c:x:y with 2≤b≤5, 1≤c≤3, 2≤x+y≤b+c and 0.1≤y≤1; Ba₂ScAlO₅; and yttrium oxide Y₂O₃ or europium oxide Eu₂O₃, wherein the target material is configured for physical thin film deposition in a production of barium-scandate dispenser cathodes or other barium-scandate materials.
